(19) United States
(12) Patent Application Publication
(10) Pub. No.: US 2026/0136889 A1
(43) Pub. Date: May 14, 2026

(54) SUBSTRATE-HOLDING DEVICE AND OPTICAL INSPECTION DEVICE HAVING SAME

(71) Applicant: Hitachi High-Tech Corporation, Tokyo (JP)

(72) Inventors: Mami FUKUMURA, Tokyo (JP); Makoto HEMMI, Tokyo (JP); Mariko MIYAZAKI, Tokyo (JP); Yoshihiro SATOU, Tokyo (JP); Toshio MASUDA, Tokyo (JP); Kei SHIBAYAMA, Tokyo (JP); Toshinori KOBAYASHI, Tokyo (JP); Akio YAZAKI, Tokyo (JP)

(21) Appl. No.: 19/119,445

(22) PCT Filed: Feb. 20, 2023
(86) PCT No.: PCT/JP2023/005894

§ 371 Date: Apr. 9, 2025

(51) Int. Cl. H10P 72/76; H10P 72/00; H10P 72/78

(52) U.S. Cl. CPC H10P 72/7624; H10P 72/0606; H10P 72/0616; H10P 72/7614; H10P 72/78

(57) ABSTRACT

Provided is a substrate-holding device capable of improving the in-plane uniformity of a wafer back surface pressure and the flatness of wafer holding, flattening not only a flat wafer but also a warped wafer, and holding a wafer in a back surface non-contact manner, and an optical inspection device including the substrate-holding device. The substrate-holding device includes a wafer chuck 102 (rotary chuck) and a clamp unit 103 that supports an edge of a substrate 101 to be rotated by the wafer chuck 102 (rotary chuck) in a radial direction and a circumferential direction of the substrate 101, in which the wafer chuck 102 is provided with a plurality of static pressure bearing pads that hold the substrate 101 in a back surface non-contact manner, the plurality of static pressure bearing pads including a plurality of gas supply ports 111 that supplies gas to the substrate 101.

### TECHNICAL FIELD

The present invention relates to a substrate-holding device, and more particularly to a substrate-holding device suitable for an optical inspection device and an optical inspection device including the substrate-holding device.

### BACKGROUND ART

In response to miniaturization of foreign matter and defect inspection in a semiconductor manufacturing process, wafer optical inspection is also required to have high sensitivity.

The wafer optical inspection includes a “back surface suction” method in which the back surface of a wafer is held in contact through vacuum suction for inspection, and an “edge grip” method in which only an edge is held but the back surface of the wafer is not in contact for inspection. In the “edge grip” method, the wafer is held by an edge clamp attached to a wafer chuck, the back surface of the wafer is supported by air pressure in a non-contact manner with respect to the wafer chuck, and the chuck translates while rotating at a high speed to inspect the entire surface of the wafer.

As a wafer chuck in the “edge grip” method, an air bearing type wafer chuck that uses air bearing to keep a supporting gap between the wafer and a chuck surface constant has recently been proposed, in addition to a back-surface air floating type wafer chuck in which air is supplied to the back surface of a wafer to correct deflection due to self-weight sinking of the wafer and support the wafer.

On the other hand, when the focal depth of an optical inspection unit decreases as the sensitivity of the optical inspection increases, it becomes difficult to keep the height variation of the wafer surface within the range of the focal depth. An autofocus mechanism can follow translational movement for radial height variation of the wafer surface, but there is a limit to amplitude-responsive bandwidth for circumferential height variation of the wafer surface to follow high-speed rotation. In addition, the wafer is not necessarily flat, and a warped wafer is also an object of optical inspection. Thus, with the decrease of the focal depth of the optical inspection unit, it becomes necessary not only to hold a flat wafer flat but also to hold a warped wafer flat and to bring the variation of the wafer height within the range of the focal depth without contacting the back surface of the wafer within the restriction of the band of the autofocus mechanism.

Further, in the wafer optical inspection, it is required not to attach foreign matters to the wafer during the inspection not only on the front surface but also on the back surface of the wafer.

As a technique related to a method of holding a wafer in a back surface non-contact manner, PTL 1 discloses a rotating wafer chuck mechanism in which a pressurized gas region including a plurality of pressurized gas elements and a depressurized gas region including a plurality of depressurized gas elements are disposed on a chuck surface, the wafer is held with its flatness is being maintained while contact of a back surface of the wafer with the chuck surface is avoided, and the wafer is held in a horizontal direction at a wafer edge.

The pressurized gas region and the depressurized gas region are alternately disposed apart from each other in the circumferential direction. Thus, the gas supplied from the pressurized gas region flows to the depressurized gas region and is exhausted. The wafer chuck mechanism is rotationally driven. Thus, the pressurized gas region, the depressurized gas region, and an intermediate region thereof also rotate in the same manner. Thus, the gas supplied from the pressurized gas region to the back surface of the wafer tends to flow outward because of the action of the centrifugal force according to the rotation radius position. The wafer is held by the pressure of the gas on the back surface of the wafer, that is, because of the balance between the positive pressure and the negative pressure. Thus, the flow and the pressure distribution of the gas on the back surface of the wafer change between the stationary state and the rotating state. As a result, the holding force distribution of the gas with respect to the wafer fluctuates, which may adversely affect the flatness of the wafer.

Thus, a technique described in PTL 2 has been proposed. PTL 2 discloses a wafer chuck in which a plurality of air bearing pads including a gas supply port for supplying gas toward a wafer and a gas exhaust port provided in an annular groove surrounding the gas supply port are disposed on a rotary chuck.

### CITATION LIST

### Patent Literatures

PTL 1: JP 2017-504199 A

PTL 2: WO 2021/240598 A

### SUMMARY OF INVENTION

### Technical Problem

However, in the configuration of PTL 2, the centrifugal force accompanying the high-speed rotation of the wafer chuck acts on the gas between the air bearing pads. Thus, the pressure of the exhaust groove or the gas exhaust port is not determined because of the exhaust pressure, and a difference in pressure characteristics occurs between the pads, which may affect the flatness of the wafer. In addition, in PTL 1 and PTL 2, flattening and holding a warped wafer is not considered.

An object of the present invention is to provide a substrate-holding device capable of improving the in-plane uniformity of a wafer back surface pressure and the flatness of wafer holding, flattening not only a flat wafer but also a warped wafer, and holding a wafer in a back surface non-contact manner, and an optical inspection device including the substrate-holding device.

### Solution to Problem

To solve the above-described problem, a substrate-holding device according to the present invention includes a rotary chuck and a clamp unit that supports an edge of a substrate to be rotated by the rotary chuck, in a radial direction and a circumferential direction of the substrate, in which the rotary chuck is provided with a plurality of static pressure bearing pads that hold the substrate in a back surface non-contact manner, the plurality of static pressure bearing pads including a plurality of gas supply ports that supplies gas to the substrate, an intake groove disposed in the radial direction and the circumferential direction in a mutually connected manner, one or a plurality of gas intake ports provided in the intake groove, and a static pressure bearing portion provided between the gas supply ports and the intake groove, and the intake groove and the one or plurality of gas intake ports are provided at positions shared with static pressure bearing pads adjacent to each other in the radial direction and the circumferential direction among the plurality of static pressure bearing pads.

An optical inspection device according to the present invention includes a substrate-holding device that holds a substrate, a focusing mechanism unit on which the substrate-holding device is placed, a rotation mechanism unit that rotates the focusing mechanism unit, a translation mechanism unit that translates the rotation mechanism unit, and an optical inspection unit including an irradiation optical system and a detection optical system, in which the substrate-holding device includes a rotary chuck and a clamp unit that supports an edge of a substrate to be rotated by the rotary chuck, in a radial direction and a circumferential direction of the substrate, the rotary chuck is provided with a plurality of static pressure bearing pads that hold the substrate in a back surface non-contact manner, the plurality of static pressure bearing pads including a plurality of gas supply ports that supplies gas to the substrate, an intake groove disposed in the radial direction and the circumferential direction in a mutually connected manner, one or a plurality of gas intake ports provided in the intake groove, and a static pressure bearing portion provided between the gas supply ports and the intake groove, and the intake groove and the one or plurality of gas intake ports are provided at positions shared with static pressure bearing pads adjacent to each other in the radial direction and the circumferential direction among the plurality of static pressure bearing pads.

### Advantageous Effects of Invention

The present invention can provide a substrate-holding device capable of improving the in-plane uniformity of a wafer back surface pressure and the flatness of wafer holding, flattening not only a flat wafer but also a warped wafer, and holding a wafer in a back surface non-contact manner, and an optical inspection device including the substrate-holding device.

Problems, configurations, and effects other than those described above will be clarified by the following description of the embodiments.

### BRIEF DESCRIPTION OF DRAWINGS

FIG. 1 is an overall schematic configuration diagram of an optical inspection device according to an embodiment of the present invention.

FIG. 2 includes a top view and a sectional view taken along the line A-A of a substrate-holding device (wafer chuck) according to Example 1 of the present invention. FIG. 3 includes a top view and a sectional view taken along the line A-A of an air bearing pad alone of the substrate-holding device (wafer chuck) according to Example 1 of the present invention.

FIG. 4 is a diagram illustrating a pressure distribution on the upper surface of the air bearing pad illustrated in FIG. 2 or the back surface of a wafer.

FIG. 5 is a diagram illustrating support characteristics, that is, a relationship between a support gap h, a support force F, and support rigidity dF/dh.

FIG. 6 includes a top view of a wafer chuck in which a plurality of air bearing pads illustrated in FIG. 3 are disposed, a diagram illustrating a pressure distribution on the back surface of a wafer and a support gap according to a position in a chuck radial direction (distance from a chuck center), and a diagram illustrating a relationship between the support gap and an angular position in a chuck outer peripheral portion.

FIG. 7 includes a top view and a sectional view taken along the line A-A, illustrating a schematic configuration of an air bearing pad described in PTL 2.

FIG. 8 is a diagram illustrating a pressure distribution on the upper surface of the air bearing pad illustrated in FIG. 7 or the back surface of a wafer.

FIG. 9 includes a top view of a wafer chuck in which a plurality of air bearing pads illustrated in FIG. 7 are disposed and a diagram illustrating a pressure distribution on the back surface of a wafer and a support gap according to a position in a chuck radial direction (distance from a chuck center).

FIG. 10 is a diagram illustrating the influence on the pressure distribution on the back surface of a wafer, the support gap, and the wafer height variation in a CLV inspection in which the rotation speed changes at a constant linear speed during the inspection.

FIG. 11 includes a top view and a sectional view taken along the line A-A of a substrate-holding device (wafer chuck) according to Example 2 of the present invention.

FIG. 12 includes a top view and a sectional view taken along the line A-A of a substrate-holding device (wafer chuck) according to Example 3 of the present invention.

### DESCRIPTION OF EMBODIMENTS

In the present specification, the “radial direction” refers to a direction from the center of a disk-shaped substrate toward an outer circumferential direction, and the “circumferential direction” refers to a direction along each circumferential direction of concentric circles of the disk-shaped substrate. The “substrate” refers to a wafer or the like. Hereinafter, a wafer inspection device will be described as an example of the optical inspection device.

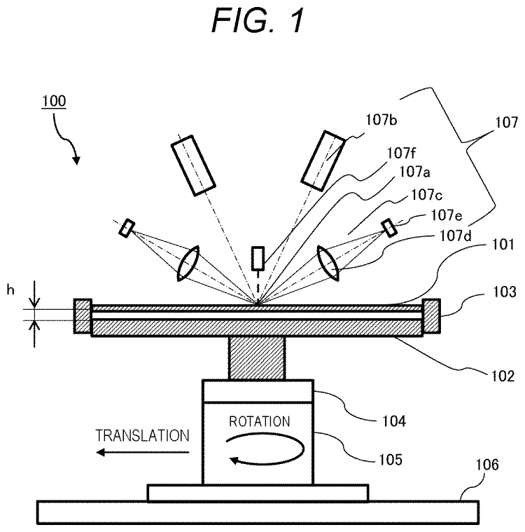

FIG. 1 is an overall schematic configuration diagram of an optical inspection device according to an embodiment of the present invention. As illustrated in FIG. 1, a wafer inspection device 100 includes a wafer chuck 102 that holds a wafer 101, a wafer-holding mechanism 103, a focusing mechanism unit 104, a rotation mechanism unit 105, a translation mechanism unit 106, and an optical inspection unit 107.

An end portion of the wafer 101 is held by the wafer-holding mechanism 103 provided in the wafer chuck 102 (also referred to as a substrate-holding device), and the back surface of the wafer is held with a support gap h between the back surface and the wafer chuck 102 in a non-contact manner with respect to the wafer chuck. The wafer chuck 102 is placed on the focusing mechanism unit 104. The rotation mechanism unit 105 rotates the wafer 101, the wafer chuck 102, and the focusing mechanism unit 104. The translation mechanism unit 106 translates the rotation mechanism unit 105 together with the wafer 101, the wafer chuck 102, and the focusing mechanism unit 104.

The entire surface of the wafer 101 is spirally inspected by the optical inspection unit 107 because of the rotational movement with the rotation mechanism unit 105 and the translational movement with the translation mechanism unit 106.

The optical inspection unit 107 includes an irradiation optical system 107b and a detection optical system 107c that are optically aligned with an inspection position 107a. The detection optical system 107c includes a detection lens 107d and a detection sensor 107e, and it detects weak scattered light from foreign matters and defects at the inspection position 107a. Further, the optical inspection unit 107 is provided with a wafer height measurement system 107f that measures the height position of the wafer 101 at the inspection position 107a, with which the wafer height is measured at the time of optical inspection, and the wafer height can be adjusted by the focusing mechanism unit 104.

With the above configuration, the wafer inspection device 100 enables optical inspection over the entire surface of the wafer 101 held by the wafer chuck 102 in a back surface non-contact manner. To ensure high sensitivity and high throughput of the optical inspection, a short wavelength laser in an ultraviolet or deep ultraviolet region is used for the irradiation optical system 107b. A condensing optical system or an imaging optical system is used as the detection optical system 107c, and a photomultiplier, a silicon photomultiplier (SiPM) that performs photon counting in multiple pixels, or a line sensor in which a large number of imaging elements are densely disposed in a line shape is used as the detection sensor 107e.

Hereinafter, the wafer chuck 102 (substrate-holding device) constituting the wafer inspection device 100 as an optical inspection device will be described in detail with reference to the drawings.

### Example 1

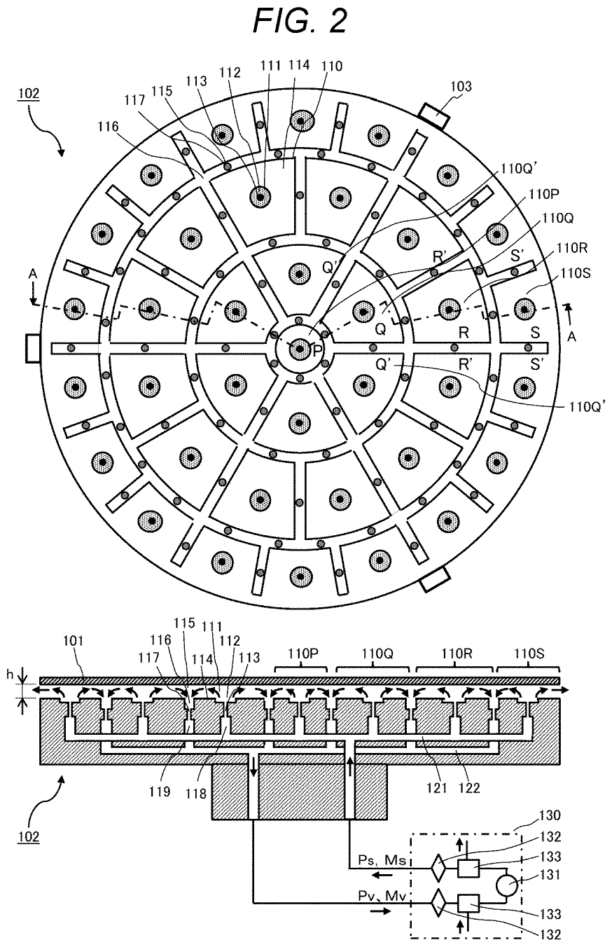

FIG. 2 includes a top view and a sectional view taken along the line A-A of a substrate-holding device (wafer chuck) according to the present example. As illustrated in the upper part of FIG. 2, a large number of air bearing pads 110 are disposed on the upper surface of the wafer chuck 102.

The air bearing pads 110 include a supply pocket 112, a supply orifice 113, and a static pressure bearing portion 114 as a gas supply port 111, and includes an intake groove 116 and an intake orifice 117 as a gas intake port 115, thereby constituting a static pressure air bearing (air bearing).

As illustrated in the lower part of FIG. 2 (sectional view taken along the one-dot chain line in the upper part), the gas supply port 111 supplies the gas from a gas supply passage 118 to the static pressure bearing portion 114 on the back surface of the wafer 101 through the supply orifice 113 and the supply pocket 112. The gas intake port 115 takes in the gas supplied from the gas supply port 111 to the static pressure bearing portion 114 on the back surface of the wafer 101 through the intake groove 116, the intake orifice 117, and the intake passage 119. With this configuration, the wafer 101 is held in a back surface non-contact state by the action of the static pressure bearing with the support gap h from the front surface of the wafer chuck 102. The static pressure bearing portion 114 is a flat portion facing the wafer 101 with the support gap h, and is formed flat with the same height in all the air bearing pads 110 on the wafer chuck 102.

In the air bearing pad 110, the gas supply passage 118 is connected to a gas supply pipe 121, and the intake passage 119 is connected to a gas intake pipe 122. The gas supply pipe 121 and the gas intake pipe 122 are mutually connected to other air bearing pads and connected to a gas supply/intake system 130.

The gas supply/intake system 130 sucks the gas from the gas intake pipe 122 via a clean filter 132 with a pump 131 and supplies the gas to the gas supply pipe 121. The pressure and flow rate of the gas are set to a pressure P_{S} and a flow rate M_{S} for gas supply, a pressure P_{V} and a flow rate M_{V} for gas intake by a pressure/flow rate control valve 133.

The gas supplied from the gas supply port 111 is taken in from the gas intake port 115. The gas supply port 111 and the gas intake port 115 are set for each air bearing pad 110 so that the flow rates of gas supply and gas intake are roughly balanced. In this case, since the flow rates of gas supply and gas intake are roughly balanced in the entire wafer chuck, the gas supply and gas intake can be cyclically performed by adjusting the flow rates with the pressure/flow rate control valve 133 without providing a large-capacity pump 131 in each of the gas supply/intake system 130.

On the other hand, the amounts of gas supply and gas intake may change because of the variation of the support gap h. In addition, when a warped wafer is flattened and held, the support gap h is different at the warped portion. In this case, there is a possibility that the flow rates of gas supply and gas intake is not balanced. Or, the supply gas flows out to the outer peripheral portion at the end portion of the wafer 101, which may cause imbalance between gas supply and the gas intake. Even in such a case, the flow rates of gas supply and gas intake can be adjusted by the pressure/flow rate control valve 133.

In the upper part of FIG. 2, the air bearing pads 110 are disposed adjacent to each other in the circumferential direction and the radial direction. The intake groove 116 is disposed so as to surround the air bearing pads 110 and is formed so as to be shared between adjacent air bearing pads 110. In other words, the intake groove 116 is provided between the gas supply ports 111 adjacent to each other in the circumferential direction and the radial direction.

For example, the intake groove 116 around an air bearing pad 110Q is shared with an air bearing pad 110Q′ adjacent in the circumferential direction and with an air bearing pad 110P and an air bearing pad 110R adjacent in the radial direction. The intake grooves 116 are formed so as to be disposed in the radial direction and the circumferential direction and connected to each other. In other words, the intake grooves 116 are formed so as to be disposed in the radial direction and the circumferential direction and communicated with each other.

Further, in the intake groove 116, a plurality of gas intake ports 115 are disposed around the air bearing pads 110. The number of the gas intake ports 115 is set in consideration of the hole diameters of the supply orifice 113 and the intake orifice 117, the supply pressure Ps, and the intake pressure Py so that the supply from the gas supply port 111 and the intake from the gas intake port 115 are substantially the same and balanced for each air bearing pad 110. It is desirable that the gas intake port 115 or the intake orifice 117 be disposed at substantially equal intervals so as not to provide a distribution difference in the in-groove pressure of the intake groove 116.

With this configuration, the gas from the gas supply port 111 is taken in by the gas intake port 115, the amount of gas supply and the amount of gas intake are balanced for each air bearing pad 110, and gas supply and gas intake do not move back and forth between adjacent air bearing pads 110. Thus, the air bearing pads 110 do not interfere with each other, and the air bearing pads 110 can operate with predetermined support characteristics.

When air bearing pads adjacent to each other do not share the intake groove 116, there is a possibility that the pressure outside the air bearing pads fluctuates to affect the support characteristics because of the action of the centrifugal force when the wafer chuck 102 rotates. However, the configuration described above can avoid such an influence. More specifically, since the supplied air from the gas supply port 111 to the air bearing pad 110 is taken in with a balanced flow rate at the gas intake port 115, even though the wafer chuck 102 rotates, the back surface air of the wafer 101 is collected in each air bearing pad and does not pass between the air bearing pad and adjacent air bearing pads. Thus, the pressure of the intake groove 116 is determined by the intake pressure, the back surface pressure of the wafer 101 becomes uniform in the plane, and the wafer 101 can be held flat.

In the upper part of FIG. 2, the shape of the air bearing pad 110 is desirably an “annular trapezoid” (a substantially trapezoidal shape in which an upper side and a bottom side are formed of a part of a circular ring) obtained by equally dividing an annular ring. The shape of the air bearing bad is not limited to this shape. For example, a “trapezoidal” shape in which the upper side and the bottom side are straight lines may be adopted. The central portion of the wafer chuck 102 may have a “circular” shape.

Regarding the arrangement of the air bearing pads 110, it is desirable that pads having substantially the same shape are equally divided and disposed in the circumferential direction. Since the wafer inspection proceeds at a high speed in the circumferential direction because of the high-speed rotation of the wafer chuck 102, this arrangement does not cause fluctuation in the inspection sensitivity in the circumferential direction. For example, when the pad support characteristics are different between the 3:00 direction and the 6:00 direction of the wafer, there is a possibility that a variation is generated in the support gap h (lower part in FIG. 2) and the focusing mechanism unit 104 cannot follow the change. However, the same support characteristic can be obtained in the circumferential direction by having the same pad shape in the circumferential direction.

On the other hand, the radial lengths of the air bearing pads 110 are not necessarily the same in the radial direction. For example, as in the present example, the radial length may be reduced at the outermost circumference.

As illustrated in the upper part of FIG. 2, in the outermost peripheral air bearing pad 110S, the intake groove 116 is not formed in the circumferential direction outside the pad. With such a configuration, as illustrated in the lower part of FIG. 2, a flow of gas toward the outer peripheral outer side at the outermost periphery is realized. This is because when the intake groove 116 is provided on the outer side of the outermost peripheral air bearing pad 110S, external air is drawn from the outer side of the wafer chuck 102 toward the back surface of the end of the wafer 101, and when foreign matters are included in the external air, there is a possibility that foreign matters adhere to the back surface of the end of the wafer 101.

Thus, by adopting a configuration in which the intake groove 116 is not formed on the outer side of the outermost peripheral air bearing pad 110S, it is possible to hold the wafer 101 in a back surface non-contact state without attaching foreign matters to the back surface of the end portion of the wafer 101.

The gas intake port 115 and the intake orifice 117 are not provided in a typically used static pressure bearing such as an air spindle. In a typical static pressure bearing, a pressure loss is given to gas supply at a supply orifice, and a high pressure is supplied to a support gap, and thus characteristics as a static pressure bearing are obtained. Thus, an intake structure is not required or provided. Although an intake structure may be provided depending on the application, even in such a case, the intake orifice 117 is not required in the intake path, but rather, it is regarded as being excluded from the design theory of the static pressure bearing as giving an unnecessary pressure loss to interrupt intake characteristics and intake efficiency. On the other hand, in the present invention, the wafer chuck 102 rotates at a high speed. That is, while a typical static pressure bearing such as an air spindle is used in a stationary state, the static pressure bearing portion is rotated at a high speed in the wafer chuck 102 of the present invention. Thus, gas supply and gas intake are strongly affected by the centrifugal force. The intake orifice 117 has been found by the inventors of the present invention as a configuration requirement necessary for preventing the action of the centrifugal force from affecting the support characteristics of the air bearing pad and the wafer flatness when the wafer chuck 102 rotates at a high speed.

As illustrated in the lower part of FIG. 2, the gas intake pipe 122 of the air bearing pad 110 is connected to another air bearing pad. Because of the action of the centrifugal force accompanying the high-speed rotation of the wafer chuck 102, the pressure of the gas in the gas intake pipe 122 increases toward the outer peripheral side. Here, in the configuration in which the intake orifice 117 is not provided, the pressure of the intake groove 116 is the same as that of the gas intake pipe 122. Thus, because of the centrifugal force accompanying the high-speed rotation, the pressure of the intake groove 116 increases on the outer peripheral side of the wafer chuck 102, the intake pressure necessary for the support characteristics of the air bearing pad 110 becomes insufficient, the support gap h is widened, and the wafer flatness is reduced. Thus, by providing the intake orifice 117 and giving a predetermined pressure loss between the intake groove 116 and the gas intake pipe 122, the rotational centrifugal force is prevented from substantially affecting the pressure of the intake groove 116, and further, the support characteristics of the air bearing pad 110, the support gap h, or the wafer flatness.

The supply orifice 113 is an essential configuration requirement as a typical static pressure bearing. At the same time, it also has a function of giving a predetermined pressure loss between the supply pocket 112 and the gas supply pipe 121, the rotational centrifugal force can be prevented from substantially affecting the pressure of the supply pocket 112, and further, the support characteristics of the air bearing pad 110 and the wafer flatness.

As the “throttle” of the static pressure bearing, in addition to “orifice throttle”, “surface throttle”, “porous throttle”, “self-throttle”, and the like are known. An “orifice throttle” is taken as a representative example of such a “throttle” in the supply orifice 113 and the intake orifice 117. Other “throttles”, for example, “supply self-generated throttle” may be used, or a “composite throttle” in which these throttles are combined may be used.

In the example of FIG. 2, the shapes of the gas supply port 111 and the gas intake port 115 constituting the air bearing pad 110 are the same in all the air bearing pads 110. However, the shapes are not necessarily the same, and the shape may be different depending on the positions in the radial direction. The hole diameters of the supply orifice 113 and the intake orifice 117 may also be different according to the positions in the radial direction. The shape of the supply pocket 112 is not limited to a circular shape. The shape and size of the air bearing pad itself may also vary depending on the positions in the radial direction. By reducing the area of the air bearing pad, the influence of a local variation occurred in the support gap because of the pressure distribution on the back surface of the wafer in the air bearing pad can be reduced. In this case, the support rigidity per air bearing pad is smaller than that of an air bearing pad having a large area. However, as the number of air bearing pads increases, almost the same support rigidity as the sum is obtained. In any of the above cases, a configuration in which there is no difference in the support rigidity of each air bearing pad with respect to the circumferential direction, which is the direction of the rotation inspection, is desirable.

The constituent material of the wafer chuck 102 is desirably, for example, lightweight and highly rigid aluminum, or ceramics such as SiC or alumina to ensure the flatness of the wafer under high-speed rotation.

The wafer chuck 102 can be produced by producing an air bearing pad or a piping structure for each single layer and forming the air bearing pad or piping structure into a multilayer structure by bonding or fastening.

To prevent foreign matters from adhering to the back surface of the wafer 101, it is desirable to perform grinding, polishing, surface treatment, and the like for reducing the foreign matter potential not only on the surface of the wafer chuck 102 but also on the gas flow path inside.

It is desirable to consider the influence of charging as the foreign matter potential. When a potential difference is generated between the wafer 101 and the wafer chuck 102 because of charging, there is a possibility that foreign matters adhere to the back surface of the wafer 101 before being discharged by the flow of gas when the foreign matters are present on the front surface of the wafer chuck 102. As the wafer chuck 102, the influence of charging can be reduced by selecting a highly conductive material or applying a conductive surface treatment.

As described above in the background art, neither PTL 1 nor PTL 2 considers “flattening and holding a warped wafer” or describes “support rigidity” necessary for warpage flattening. First, technical requirements such as “support rigidity” necessary for realizing not only “holding a flat wafer flat” but also “holding a warped wafer flat”, and requirements required as an optical inspection or an optical inspection device will be described in detail with reference to the examples of FIGS. 1 and 2 together with numerical examples.

Here, refer back to FIG. 1. The requirement as the optical inspection is to set the variation of the height position of the surface of the wafer 101 within the range of the focal depth of the optical inspection unit 107. For example, when the focal depth of the optical inspection unit 107 is ±1 μm, the requirement as the optical inspection can be realized by setting the flatness of the entire surface of the wafer 101 to ±1 μm without using the height position correction on the wafer chuck 102 with the focusing mechanism unit 104.

When the height position of the wafer chuck 102 is corrected by the focusing mechanism unit 104, the flatness required for the wafer 101 is calculated as a value obtained by adding the height position correction range of the focusing mechanism unit 104 to the focal depth of the optical inspection unit 107 (not simple addition, but mean square sum or the like).

The focusing mechanism unit 104 that performs the height position correction on the wafer chuck 102 may perform correction according to the translation of the translation mechanism unit 106 in the radial direction, but it is needed to perform correction following the high-speed rotation with the rotation mechanism unit 105 in the circumferential direction. Here, since the bandwidth of the amplitude-response followability of the focusing mechanism unit 104 is limited, it is necessary to consider that the flatness required for the wafer 101 is different between the radial direction and the circumferential direction.

For a Φ300 wafer, as an example, in the radial direction, when the wafer chuck translates a wafer radius of 150 mm in 5 seconds, the moving speed is 30 mm/sec, and the focusing mechanism unit 104 easily follows in the radial direction. On the other hand, in the circumferential direction, in the case of a rotation speed of 3000 rpm (50 Hz), the rotation speed on the outer periphery of the wafer becomes as high as 47 m/s, and the focusing mechanism unit 104 is required to have a high-speed response of at least 50 Hz or more in the circumferential direction. Thus, the followability of the mechanism unit may be limited.

The following numerical values are simplified for the sake of easy understanding of the present example. As an example, the height position correction range with the focusing mechanism unit 104 is set to ±10 μm in the radial direction and ±1 μm in the circumferential direction, and the flatness required for the wafer 101 is set to ±10 μm in the radial direction and ±1 μm in the circumferential direction.

The flatness actually required for the wafer 101 is a value obtained by adding the height position correction range ±1 μm of the focusing mechanism unit 104 to the focal depth of the optical inspection unit 107 (not simple addition, but mean square sum or the like), but here, the flatness is simplified and considered as the same value as the height correction range of the focusing mechanism unit 104. Here, “flat” or “flatness” does not mean “flat” or “flatness” on the order of nanometers (nm), and it should be noted that the range on the order of micrometers (μm) is provided in consideration of the focal depth of the optical inspection unit 107 and the height position correction range of the focusing mechanism unit 104.

Next, the requirements required for “flat holding of a flat wafer” and “flat holding of a warped wafer” will be described with reference to FIG. 2.

“Holding a flat wafer flat” can be realized by holding a “flat wafer” so as to keep the support gap h between the back surface of the wafer 101 and the front surface of the wafer chuck 102 constant within the range of the focal depth of the optical inspection unit 107 over the entire surface of the wafer 101 in the lower part of FIG. 2 as long as the flatness of the “flat wafer” itself is within the focal depth of the optical inspection unit 107.

As an example using the above numerical values, when the variation width of the support gap h between the back surface of the wafer 101 and the front surface of the wafer chuck 102 is within ±1 μm over the entire surface of the wafer 101, it is possible to “hold the flat wafer flat”.

For a “warped wafer”, even in a case where the flatness of the wafer exceeds the focal depth of the optical inspection unit 107, the height position of the surface of the wafer 101 can be kept constant within the range of the focal depth of the optical inspection unit 107 by applying the height position correction performed by the focusing mechanism unit 104 as long as the height position correction is within the applicable range. In this case, the correction range is limited to the restriction range with the amplitude-response followability band of the height position correction performed by the focusing mechanism unit 104, and the correction range is the flatness ±10 μm for the variation of the flatness in the radial direction and ±1 μm for the circumferential direction.

In a “warped wafer”, when the variation in the flatness of the wafer greatly exceeds the focal depth of the optical inspection unit 107 and also exceeds the band range of the amplitude-response followability of the height position correction performed by the focusing mechanism unit 104, it is necessary to “flatten and hold the warped wafer”. To “flatten and hold the warped wafer” in this manner, not only the “support gap h” but also “support rigidity” as a static pressure bearing needs to be considered for the air bearing pad or the wafer chuck 102 using the air bearing pad.

In general, “support rigidity” in a static pressure bearing is a “ratio of a change in the support gap to the variation amount of a support force”, and “large support rigidity” means “small change in the support gap”. Or, conversely, the “support rigidity” is a “ratio of a change in the support force to the variation amount of the support gap”, and the “large support rigidity” means that when the support gap has changed from a predetermined design value, the support force changes so as to be returned to the design support gap, and the change in the support force as the returning action is large.

When the wafer chuck 102 using the air bearing pad is to “flatten and hold a warped wafer”, the support gap h is larger in the “warped portion” of the wafer 101 than in the “flat portion”. By causing an air bearing pad having high support rigidity to act as a static pressure bearing on the “warped portion”, a support force acts so as to pull back the wide support gap of the “warped portion” to the support gap of the “flat portion”, and the change in the support gap h between the “warped portion” and the “flat portion” is reduced, that is, the wafer can be held with the “warpage being flattened”.

The value of the warpage of the wafer is allowed up to 100 μm in the standard of the wafer. In general, this value greatly exceeds the focal depth of the optical inspection unit 107. The shape of the wafer warpage varies from wafer to wafer, but can be classified into several types. The shape includes a mountain shape in which the central portion is high, a bowl shape in which the outer circumference has a uniform outer height, and a shape with the outer circumference having an outer height at 1 to 2 places (with one height: end warpage, with two heights: saddle-shaped warpage).

An air bearing pad or the wafer chuck 102 using the air bearing pad is required to secure support rigidity of a sufficient size for “flattening a warped wafer” with respect to a warped wafer having such a large warpage value and various warpage shapes. When the “warped wafer can be flattened” by the wafer chuck 102, the optical inspection of the wafer can be performed by applying the height position correction performed by the focusing mechanism and making the variation of the wafer flatness within the focal depth of the optical inspection unit 107.

For example, among the warped shapes described above, the amount of warpage changes mainly in the radial direction of the wafer 101 with a warpage with a high central portion (mountain shape) or with an outer height (bowl shape) uniformly on the outer periphery. Thus, when the wafer is flattened by securing high support rigidity at the central portion and the outer periphery, the optical inspection of the wafer can be performed by applying the height position correction performed by the focusing mechanism unit 104 in the radial direction.

For example, when the numerical value of the above example is used, a warped wafer having an outer peripheral height of 100 μm is flattened and held by flattening the warpage in the radial direction to 10 μm, and the height position is corrected in the radial direction by the focusing mechanism unit 104, whereby the wafer flatness or the variation in the wafer height can be made within the focal depth of the optical inspection unit 107, and the wafer optical inspection can be performed.

On the other hand, regarding the warpage of the outer height at a plurality of positions on the outer periphery (with one height: end warpage, with two heights: saddle-shaped warpage), the amount of warpage changes not only in the radial direction of the wafer 101 but also in the circumferential direction. Since the application of the height position correction performed by the focusing mechanism unit 104 is in the range of ±1 μm in the circumferential direction because of the band limit of amplitude-response following, the wafer flatness or the wafer height is within the range of the focal depth of the optical inspection unit 107 by applying the height position correction performed by the focusing mechanism unit 104 in the circumferential direction after securing higher support rigidity and flattening the warp in the circumferential direction at the outermost peripheral portion where the warp is large, and the optical inspection of the wafer can be performed.

For example, when the numerical value of the above example is used, a wafer warped into a saddle shape by 100 μm at two locations on the outer periphery is flattened to 1 μm in the circumferential direction and held, and thus the range of the height position correction performed by the focusing mechanism unit 104 becomes ±1 μm at last, and the wafer optical inspection can be performed.

In this manner, to “flatten a warped wafer” with respect to a warped wafer having a large warpage value and various warpage shapes with the wafer chuck 102, the air bearing pad is required to obtain predetermined support characteristics required based on the positions in the radial direction, that is, to be able to secure necessary support rigidity with a predetermined support gap and support force. In addition, the wafer chuck 102 is required to be capable of setting a predetermined support characteristic depending on the radial position in the plane of the wafer chuck 102, for example, securing a larger support rigidity at the outermost peripheral portion.

In the air bearing pad 110 of the present example, as will be described later, predetermined support characteristics can be obtained with dimensional specifications and the like of the gas supply port 111 and the gas intake port 115. Then, it is possible to “flatten a warped wafer” with respect to a warped wafer having a large warpage value or various warpage shapes by disposing the air bearing pad in which predetermined support characteristics are set based on the positions in the radial direction in the plane of the wafer chuck 102 according to the radial position. By applying the height position correction with the focusing mechanism is applied to the “wafer held flat” or the “wafer whose warpage is flattened and held”, the variation in the wafer height can be made within the focal depth of the optical inspection unit 107, and the wafer optical inspection can be performed.

As described above, PTL 1 and PTL 2 do not consider “flattening and holding a warped wafer”, and do not disclose suggest “support rigidity”. The present invention focuses on this point, and according to the present example, it is possible to “hold a flat wafer flat” and “flatten and hold a warped wafer” in a non-contact state with respect to the back surface of the wafer 101 by realizing the wafer chuck 102 capable of setting the support characteristics (support force, support gap, and support rigidity) for the wafer 101 with a high degree of freedom in the plane of the wafer chuck 102.

More specifically, to keep the “support gap” between the wafer 101 and the wafer chuck 102 constant in the wafer chuck plane to “hold a flat wafer flat”, the air bearing pad is set to ensure “support rigidity” for holding the wafer 101 against a change in the support gap with respect to a predetermined support gap.

Further, it is possible not only to “hold a flat wafer flat” but also to “flatten and hold a warped wafer” by disposing the air bearing pads 110 in which predetermined support characteristics (support force, support gap, and support rigidity) are set based on the positions in the radial direction in the surface of the wafer chuck 102 so as to share the intake groove with adjacent air bearing pads in accordance with the positions in the radial direction. In this case, the setting of the support gap is not limited to be constant in the plane of the wafer chuck, but may be changed in the radial direction within the range of correction in the radial direction with the focusing mechanism unit 104. For example, by narrowing the setting of the support gap at the outermost peripheral portion to increase the support rigidity, characteristics of flattening the warpage at the outermost peripheral portion can also be improved.

By applying the height position correction performed by the focusing mechanism unit 104 to a flat wafer held flat or a wafer whose warpage is flattened and held, the variation in the height position of the surface of the wafer 101 can be made within the focal depth of the optical inspection unit 107, as a requirement for the wafer optical inspection. This makes it possible to perform wafer inspection in the “edge grip” method of holding only the edge of the wafer 101 in a back surface non-contact state corresponding to not only a flat wafer but also a warped wafer even when the focal depth of the optical inspection unit 107 is small.

As illustrated in the upper part and the lower part of FIG. 2, according to the configuration of the present example, the support characteristics (support gap, support force, support rigidity) of the air bearing pad 110 as a static pressure air bearing are defined by the area and shape of the air bearing pad 110, the specifications (area, shape, diameter, and depth of the supply pocket 112 and the supply orifice 113) of the gas supply port 111, the specifications (area, shape, diameter, and depth of the intake groove 116 and the intake orifice 117) of the gas intake port 115, and the pressure and flow rate (supply pressure Ps, supply flow rate Ms, intake pressure Pv, and intake flow rate Mv) of gas supply and gas intake.

The setting of the predetermined support characteristics (support force, support gap, and support rigidity) for the air bearing pad includes, for example, setting the area and shape of the air bearing pad 110 according to the radial position of the air bearing pad 110, and securing higher support rigidity at the outer peripheral portion according to the specifications of the gas supply port 111 and the gas intake port 115.

These settings make it possible to provide a wafer-holding device (substrate-holding device) capable of setting the support gap h and the support rigidity in the plane of the wafer chuck 102 and the wafer inspection device 100 including the wafer-holding device.

Hereinafter, with respect to the wafer chuck 102 according to the present example illustrated in FIG. 2, the support characteristics of the air bearing pad 110 will be described with a single unit model, and then, “flat holding of a flat wafer” and “flat holding of a warped wafer” with the wafer chuck 102 on which the air bearing pad is disposed will be described.

FIG. 3 includes a top view and a sectional view taken along the line A-A of an air bearing pad alone of the substrate-holding device (wafer chuck) according to the present example. The air bearing pad 110 illustrated in the upper part of FIG. 2 has a substantially trapezoidal shape (the upper side and the bottom side are configured by a part of a circular ring), but is schematically represented by a quadrangle in the upper part of FIG. 3.

As illustrated in the upper part and the lower part of FIG. 3, the air bearing pad 110 includes, as in FIG. 2, the supply pocket 112, the supply orifice 113, and the static pressure bearing portion 114 as the gas supply port 111, and includes the intake groove 116 and the intake orifice 117 as the gas intake port 115, thereby constituting a static pressure air bearing (air bearing). Gas is supplied to the air bearing pad 110 through the supply orifice 113 and the supply pocket 112, passes through the static pressure bearing portion 114, and is taken in through the intake groove 116 and the intake orifice 117. The gas pressure and the gas flow rate are set to the supply pressure Ps and supply flow rate Ms for gas supply, and the intake pressure Pv and intake flow rate Mv for gas intake. The supply flow rate Ms and the intake flow rate Mv are set to be roughly balanced for each pad. The intake groove 116 is shared with adjacent pads around the air bearing pad 110. In FIG. 3, a part of adjacent pads is displayed, and the boundary with the adjacent pads is indicated by a broken line. With this configuration, the wafer 101 can be held in a non-contact manner with the surface of the air bearing pad 110 with the support gap h.

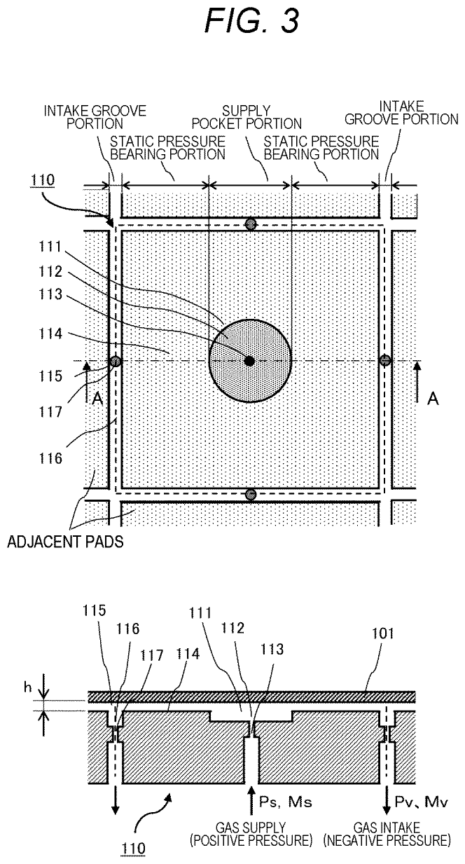

FIG. 4 is a diagram illustrating a pressure distribution on the upper surface of the air bearing pad 110 illustrated in FIG. 3 or the back surface of the wafer 101. As illustrated in FIG. 4, a high positive pressure is generated in the “supply pocket portion” in the central portion of the air bearing pad, and the pressure decreases toward the outer periphery in the “static pressure bearing portion”. Here, the pressure changes from the positive pressure (repulsion) to the negative pressure (aspiration), and the negative pressure is generated because of the intake in the “intake groove” portion.

Here, the principle of wafer support with the air bearing pad is described in PTL 2. Specifically, the wafer is held with a design support gap h0 when the repulsive force due to the positive pressure and the aspiration force due to the negative pressure are balanced with the weight of the wafer itself. When the support gap is small (h<h0), the positive pressure (repulsion) becomes larger than the negative pressure (aspiration), and a force in a direction to increase the support gap is generated. When the support gap is large (h>h0), the positive pressure (repulsion) becomes smaller than the negative pressure (aspiration), and a force in a direction to decrease the support gap is generated.

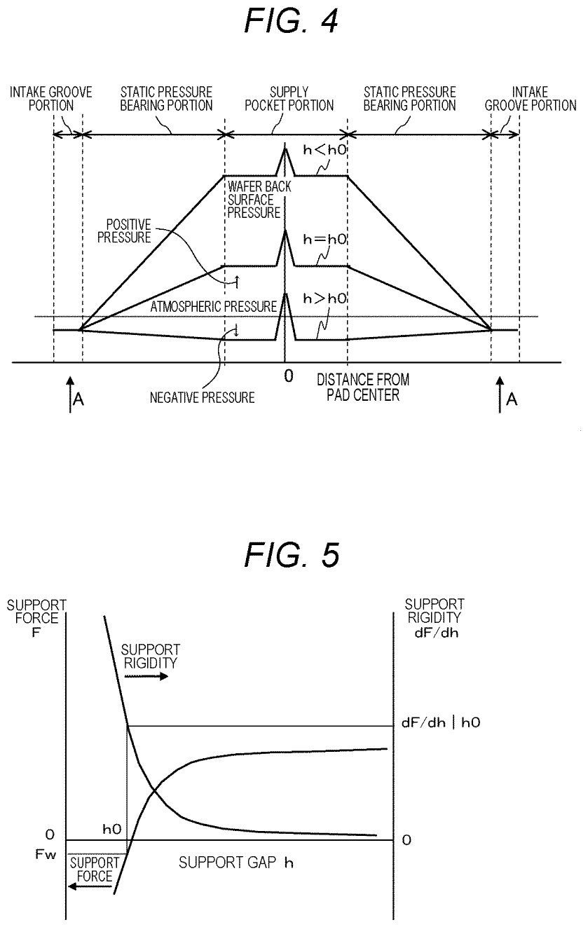

FIG. 5 is diagram illustrating support characteristics, that is, a relationship between the support gap h, the support force F, and the support rigidity dF/dh. As illustrated in FIG. 5, in a region smaller than the design support gap h0 (h<h0), the support force F is negative, that is, a force in a direction to increase the support gap is generated. In a region larger than the design support gap h0 (h>h0), the support force F is positive, that is, a force in a direction to decrease the support gap is generated. Here, the design support gap h0 is a support gap corresponding to the wafer load Fw per air bearing pad. The support rigidity dF/dh is a change amount of the support force with respect to the variation of the support gap, and a high support rigidity dF/dh|h0 is obtained in the vicinity of the design support gap h0.

In general, a static pressure bearing applies pressure to a narrow support gap to supply gas, thereby receiving a load with high support force and support rigidity. On the other hand, in the wafer chuck 102 according to the present example, since a wafer (φ300, weight 170 gf) is held by several tens of air bearing pads, the support force Fw per air bearing pad is a light load of several gf. Thus, by taking in gas in addition to gas supply, the repulsive force with the positive pressure and the aspiration force with the negative pressure are balanced with the weight of the wafer itself, and it is possible to obtain sufficient support rigidity for flattening the wafer warpage while making the support force Fw a light load of several gf.

Here, refer back to FIG. 4. Negative pressure is generated because of the intake in the “intake groove” portion. In the present example, even though the support gap h changes, the pressure of the “intake groove” portion is kept constant. As illustrated in FIG. 3, the intake groove 116 is shared between adjacent pads, and the supply flow rate Ms and the intake flow rate Mv of gas are set to be balanced for each pad. Thus, even when the support gap h has changed, the intake flow rate Mv sucked in the “intake groove” portion is rate-controlled by the supply flow rate Ms, and the pressure in the “intake groove” is maintained at a constant value determined by the intake pressure Pv.

In the wafer chuck 102 in the upper part of FIG. 2, the intake groove 116 is disposed so as to surround the air bearing pads 110 and is formed so as to be shared by adjacent air bearing pads. With such a configuration, as illustrated in FIG. 4, the pressure of the “intake groove” portion is kept constant, and predetermined support characteristics can be stably obtained even when the support gap h has changed by further balancing the flow rates of supply and intake for each air bearing pad. Further, since the gas supplied to the air bearing pad 110 is taken in by the intake groove 116, the supplied gas is collected in each air bearing pad even when the wafer chuck 102 rotates at a high speed. That is, the flow rate and the pressure of the gas on the back surface of the wafer 101 are maintained at a predetermined value determined according to the support gap because of the air bearing pads disposed on the entire surface of the wafer chuck 102. Thus, the flatness of the wafer 101 is not affected by the rotational centrifugal force, and the flatness is kept constant.

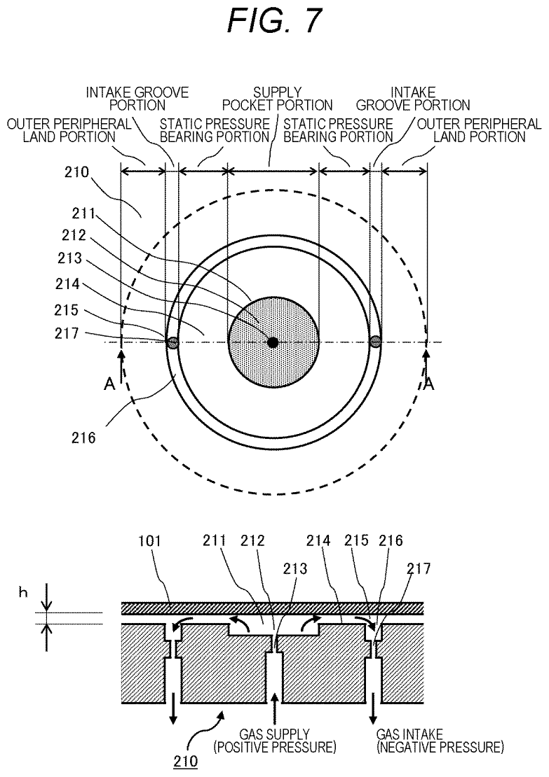

As will be described later with reference to FIG. 7, in a wafer chuck in which a single air bearing pad is disposed without sharing an intake groove with adjacent air bearing pads, gas flows into the “intake groove” portion from the outside of the air bearing pad, or gas that cannot be taken in flows out to the outside of the air bearing pad. Since the inflow and outflow amounts change depending on the support gap h, when the support gap h has changed, the pressure of the “intake groove” portion fluctuates and tends to deviate from predetermined support characteristics. When the wafer chuck rotates at a high speed, a rotational centrifugal force acts on the gas outside the air bearing pad, and the flow of the gas, the flow rate and the pressure, the pressure of the “intake groove” portion, and the distribution on the flow rate and the pressure of the back surface of the wafer change, and thus, the wafer flatness is easily affected by the rotation.

On the other hand, in the present example illustrated in FIG. 2 or 4, it is an effect obtained by the configuration of the present example that predetermined support characteristic can be stably obtained even when the support gap h has changed and even in high-speed rotation by sharing the intake groove 116 with adjacent pads (air bearing pads) and balancing the flow rates of supply and intake.

Next, setting of the support characteristic will be described. As illustrated in FIG. 4, the back surface pressure of the wafer greatly changes in the “supply pocket portion” because of the change in the support gap. That is, in the supply pocket portion, the change in the support force due to the change in the support gap is large, and high “support rigidity” is obtained. When the area ratio of the supply pocket portion at which high support rigidity can be obtained is increased, a pad having higher support rigidity can be obtained. The hole diameter of the supply orifice 113 is a basic dimension that determines the support characteristic of the static pressure bearing. The hole diameter and the number of the intake orifices 117 are also determined by the balance between supply and intake. With these shape dimensions, the support characteristics for the wafer, that is, the relationship between the support gap, the support force, and the support rigidity can be set with a high degree of freedom. In the wafer chuck 102 in FIG. 2, the air bearing pads 110 having predetermined support characteristics set according to the radial position as described above are disposed adjacent to each other in the circumferential direction and the radial direction.

As a mere example, the dimensions that affect the characteristics of the static pressure bearing of the air bearing pad are desirably 0.3 to 1 mm in diameter for the supply orifice 113, 0.3 to 2 mm in diameter for the intake orifice 117, and 0.1 to 1 mm in depth for the supply pocket 112.

The orifice minimum diameter is determined from the accuracy and stability of production in which a large number of air bearing pads are hole-processed in a metal material or ceramics that is a material of the wafer chuck. The maximum orifice diameter is determined based on conditions such as support characteristics of the static pressure bearing or reduction of influence with rotational centrifugal force. The depth of the supply pocket is set to be small so as not to cause a gas rectified flow in the supply pocket portion or self-excited vibration of the static pressure bearing.

The pressure of the gas of supply and intake is desirably the supply pressure Ps/Pa=1.0 to 2.0 and the intake pressure Pv/Pa=0.999 to 0.9 (Pa: atmospheric pressure).

To flatly hold the wafer 101, the design support gap is desirably h0=0.01 mm to 0.10 mm, and the support rigidity is desirably 101 to 103 N/mm per air bearing pad.

Regarding the value of the support rigidity, a static pressure bearing is generally used for an air spindle or the like, and high support rigidity is obtained with a design support gap set to 10 μm (0.01 mm) or less. The support rigidity is, for example, 10¹ to 10³ N/μm (10⁴ to 10⁶ N/mm). This is a value applicable to a rigid body such as an air spindle bearing.

In the wafer chuck 102 according to the present example, when the design support gap is reduced to 10 μm (0.01 mm) or less like a typical static pressure bearing to excessively increase the support rigidity, there is a possibility that the design support gap may become a factor of local deformation of the wafer in the supply pocket or the intake groove of the air bearing pad portion. Since the wafer is as thin as about 0.8 mm even with a diameter of 300 mm, it is easily conceived that the support rigidity should be set to an appropriate value according to the wafer rigidity. When the design support gap is as small as 10 μm (0.01 mm) or less, the possibility that the front surface of the wafer chuck 102 and the back surface of the wafer come into contact with each other also increases.

For these reasons, in the wafer chuck 102 according to the present example, the design support gap is desirably 0.01 mm or more. In this case, the support rigidity necessary for wafer warpage flattening is calculated to be 101 to 103 N/mm per air bearing pad from the rigidity analysis of the static pressure bearing. When the support gap is 0.1 mm or less, the flow between the wafer and the wafer chuck becomes a viscous flow, and is hardly affected by the rotational centrifugal force. Thus, the support gap is desirably 0.1 mm or less. For example, by designing the air bearing pad with the support gap of about 0.05 mm, predetermined support rigidity necessary for flattening the warpage of the wafer can be obtained.

As an example, the rotation speed of the wafer chuck 102 is assumed to be 500 to 6000 rpm at the time of inspection. Alternatively, low-speed rotation at a low speed such as 5 rpm to 2000 rpm is also assumed. When the rotation speed is increased, the number of wafers that can be inspected in a certain period of time can be increased, and when the rotation speed is decreased, inspection sensitivity to minute foreign matters and defects can be improved. In the wafer inspection device 100, since the entire surface of the wafer 101 is inspected in a spiral shape, the linear velocity is higher toward the outer periphery. Using the wafer chuck 102 according to the present example makes it possible to also apply constant line velocity (CLV) inspection in which the rotation speed is changed during inspection so that the linear speed is constant instead of the constant rotation speed. For example, by performing the CLV inspection so as to be 3000 rpm on the inner circumference and 1000 rpm on the outer circumference, the inspection speed on the inner circumference can be increased while keeping the inspection sensitivity constant at a constant linear speed.

In the process until the wafer 101 is placed on the wafer chuck 102, a wider support gap, for example, h=0.1 to 0.3 mm is also used. By changing the combination of the supply pressure Ps and the intake pressure Pv stepwise or temporarily, placing the wafer on the wafer chuck can be started with the support gap h>0.1 mm, the wafer can be held with the support gap h<0.1 mm, and the flattening can be completed with the design support gap h0. For example, a wafer can be supported and held, or a warped wafer can be flattened and held with a chucking process of floating and supporting the wafer only by the supply pressure Ps at the support gap 0.3 mm, starting the holding with the intake pressure Pv as a negative pressure close to the atmospheric pressure at the support gap h=0.1 mm, and flattening the warpage while the supply pressure Ps and the intake pressure Pv are brought close to predetermined values at the support gap h<0.1 mm to complete the flattening at the design support gap h0.

As described above, by using the wafer chuck 102 in which the air bearing pads 110 having predetermined support characteristics set according to the position in the radial direction are disposed adjacent to each other in the circumferential direction and the radial direction so as to share the intake groove 116 with the adjacent pads (adjacent air bearing pads), it is possible to “flatten and hold the warped wafer”, and further, by making the wafer flatness within the focal depth of the optical inspection in conjunction with the application of the height position correction with the focusing mechanism, the optical inspection can be realized.

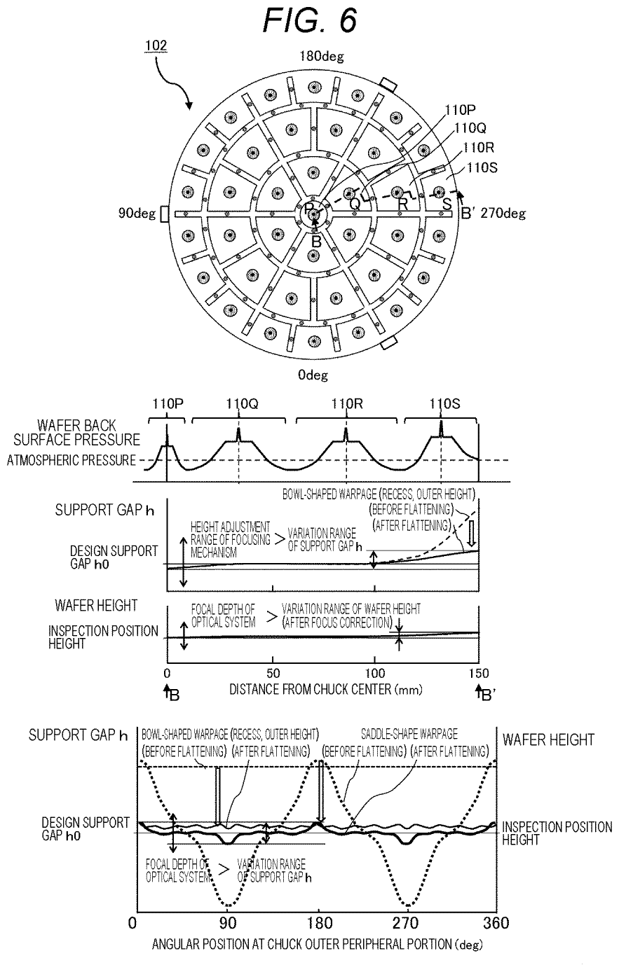

The upper part of FIG. 6 illustrates a top view of the wafer chuck 102 of FIG. 2, and describes an angular position (0 deg or the like). The air bearing pad 110 has predetermined support characteristics set according to the radial position. For example, the pad shape is set such that a circular pad is formed on the innermost circumference (P), an annular trapezoid close to a fan shape is formed on the inner side (Q), an annular trapezoid is formed on the outer side (R), and an annular trapezoid is formed on the outermost circumference(S) with small height and small width. As the specifications, for example, the rotation speed of the wafer chuck 102 is 3000 rpm, and the design support gap h0 is 0.05 mm. Although not illustrated in the drawing, dimensional specifications of the supply pocket, the supply orifice, the intake orifice, and the like are common. Of course, these specifications may be set according to the positions in the radial direction.

The middle part of FIG. 6 illustrates the pressure distribution on the back surface of the wafer, the support gap, and the warpage flattening in the radial direction according to the position (distance from the chuck center) in the chuck radial direction in the upper B-B′ part of FIG. 6. These are results of coupled analysis in which the inventors of the present invention performed rigid body analysis of wafer support based on fluid analysis of pressure distribution on the back surface of the wafer. 110P to 110S in the drawing correspond to the air bearing pad positions illustrated in the upper part of FIG. 6. The distribution of the wafer back surface pressure has a constant value of the negative pressure in the intake groove portion between the pads 110P, 110Q, 110R, and 110S. The pressure of the static pressure bearing portion is, from the central portion to the outer peripheral portion, slightly small at the pad 110P, and becomes the same value at 110Q and 110R, and the wafer back surface pressure becomes the atmospheric pressure at the outer portion at the outermost peripheral pad 110S.

Reflecting these, the support gap h is also slightly small at 110P of the innermost circumference, and is constant at 110Q and 110R. Although the wafer back surface pressure is distributed in each pad, by setting the support rigidity of the pad to an appropriate value according to the wafer rigidity as described above, the influence of the fluctuation of the wafer back surface pressure due to the intra-pad distribution becomes sufficiently small, and the support gap h changes smoothly.

In the wafer 101, the air bearing pads 110Q and 110R are originally flat, and it can be seen that the flat portion of the wafer can be held flat, that is, the flat wafer can be held flat by maintaining the wafer back surface pressure at a generally constant value.

In the outermost peripheral portion, the result of “flattening of warpage” of the wafer is also illustrated. For a bowl-shaped (recessed) warped wafer, that is, a wafer having an outer height at the outermost peripheral portion, the warpage exceeds the range of height position correction with the focusing mechanism before flattening (indicated by a broken line). However, by flattening the warpage, the support gap is slightly wide in the outermost peripheral pad 110S, but the height position can be corrected by the focusing mechanism.

With the configuration of the present example, “flat holding of a flat wafer” and “flat holding of a warped wafer” can be realized. Here, by correcting the height position with the focusing mechanism, the variation of the wafer height becomes smaller than the focal depth of the optical system, and the wafer inspection can be performed on a flat wafer and a warped wafer.

The lower part of FIG. 6 illustrates flattening of a warped wafer in the circumferential direction according to the present example, and is a diagram illustrating the relationship between the support gap and the angular position (illustrated in the upper part of FIG. 6) at the outer peripheral portion of the wafer chuck 102. The middle part of FIG. 6 illustrates the warpage flattening in the radial direction, and the lower part of FIG. 6 illustrates the warpage flattening in the circumferential direction, which is the result of analysis by the inventors of the present invention as in the middle part of FIG. 6. The warpage of the wafer can be classified into several types as described above, but as a representative example, the results in the case where the outer circumference is uniformly high (bowl-shaped) and the outer circumference is uniformly high at two places and low at two places (saddle-shaped warpage) with respect to the warpage are shown.

When the outer circumference is uniformly high (bowl-shaped), the value of the support gap is large at a constant value in the circumferential direction before flattening (dashed thin line), but is small after flattening (solid thin line). Although the vertical axis scale is not described, the amount of warpage is 100 μm before flattening and 1 μm or less after flattening. The slight unevenness after flattening (solid thin line) reflects the circumferential configuration and disposition of the outermost peripheral pad 110S in the upper part of FIG. 6, and is protruded at the supply pocket and recessed at the intake groove. This unevenness variation is sufficiently small, and is within the range of the focal depth of the inspection optical system over the circumferential direction without using the height position correction with the focusing mechanism.

When the outer peripheral portion is high at two positions and low at two positions (saddle-shaped warpage), the value of the support gap is a large value that is positive at 0 and 180 degrees and negative at 90 and 270 degrees in the circumferential direction before flattening (thick dashed line). After the flattening (solid thick line), warpage at these angular positions slightly remains, and there is slight unevenness variation reflecting the configuration and disposition of the outermost peripheral pad 110S, but even in this case, the variation is within the range of the focal depth of the inspection optical system over the circumferential direction.

In either case, the variation of the wafer height becomes smaller than the focal depth of the inspection optical system without using the height position correction with the focusing mechanism, and the wafer inspection of a warped wafer can be performed.

From the above, it is possible not only to “hold a flat wafer flat” but also to “flatten and hold a warped wafer” by disposing the air bearing pad 110 for which predetermined support characteristics are set in such a manner as to share the intake groove between adjacent pads (adjacent air bearing pads) according to the radial position in the plane of the wafer chuck 102. Further, by applying the height position correction performed by the focusing mechanism unit 104 according to the bandwidth of the amplitude-response followability of the focusing mechanism, it is possible to make the height position of the surface of the wafer 101 within the range of the focal depth of the optical inspection unit 107, which is a requirement as the optical inspection. This makes it possible to perform wafer inspection in the “edge grip” method of holding only the edge of the wafer in a back surface non-contact state corresponding to “a flat wafer” and “a warped wafer” even when the focal depth of the optical inspection unit 107 is small.

In the example of FIGS. 2 and 4, it has been described that the effect obtained by the configuration of the present example is that the intake groove 116 is shared with adjacent pads (adjacent air bearing pads) to balance the flow rates of the supply and the air intake, and thus the predetermined support characteristics are stably obtained even when the support gap h has changed and even in high-speed rotation, and that such an effect is hardly obtained in the wafer chuck in which the single air bearing pad is disposed without sharing the intake groove with adjacent pads (adjacent air bearing pads).

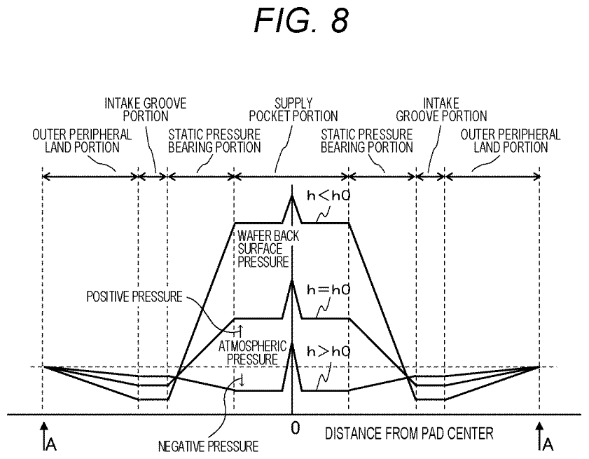

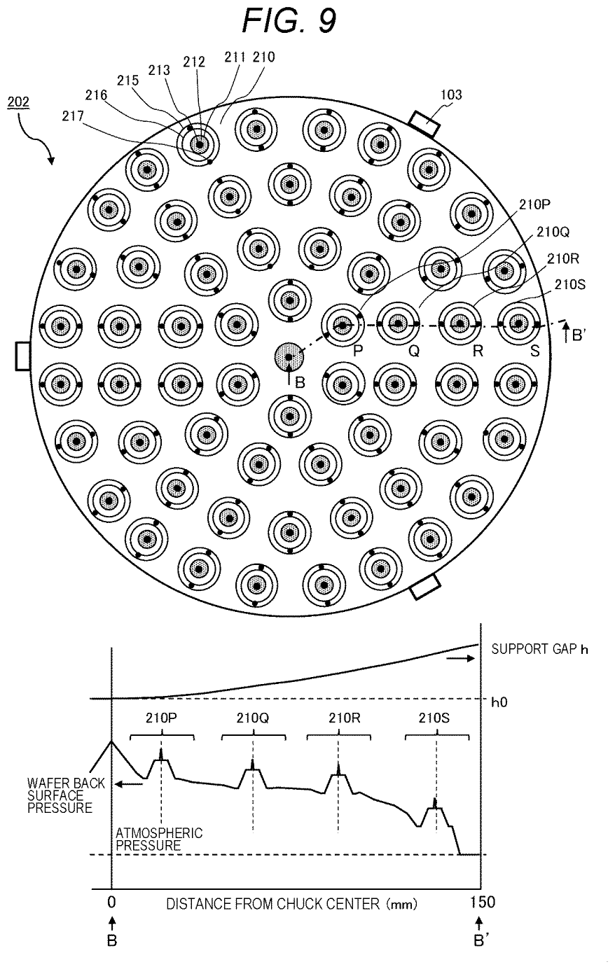

FIG. 7 includes a top view and a sectional view taken along the line A-A illustrating a schematic configuration of a single air bearing pad described in PTL 2, and FIG. 8 is a diagram illustrating a pressure distribution on an upper surface of the air bearing pad illustrated in FIG. 7 or the back surface of a wafer. FIG. 9 includes a top view of a wafer chuck in which a plurality of air bearing pads illustrated in FIG. 7 are disposed and a diagram illustrating a pressure distribution on the back surface of a wafer and a support gap according to a position in a chuck radial direction (distance from a chuck center).

As illustrated in FIG. 7, an air bearing pad 210 includes a supply pocket 212, a supply orifice 213, and a static pressure bearing portion 214 as a gas supply port 211, and includes an intake groove (annular shape) 216 and an intake orifice 217 as a gas intake port 215, thereby constituting a static pressure air bearing (air bearing). Gas is supplied to the air bearing pad 210 via the supply orifice 213 and the supply pocket 212, and is taken in via the intake groove (annular shape) 216 and the intake orifice 217, whereby the wafer 101 is held in a non-contact manner having the support gap h.

In FIG. 7, the air bearing pad 210 forms, for each pad, a pair of supply/intake ports having one air intake groove (annular shape) 216 in one has supply port 111 similarly to FIG. 3, but the difference from FIG. 3 is that the intake groove (annular shape) 216 is not shared with adjacent pads.

As illustrated in FIG. 8, a high positive pressure is generated in the “supply pocket portion” in the central portion of the air bearing pad, the pressure decreases toward the outer periphery in the “static pressure bearing portion” and the wafer back surface pressure changes from the positive pressure (repulsion) to a negative pressure (aspiration), and the negative pressure is generated at the “intake groove” portion because of the intake. These are the same as those in FIG. 4, but are different from those in FIG. 4 in that the wafer back surface pressure becomes the atmospheric pressure toward the pad outer edge portion at the “outer peripheral land portion” of the air bearing pad 210, and the wafer back surface pressure at the “intake groove” and the “outer peripheral land portion” is affected by the support gap.

This is because gas flows into the “intake groove” portion from the outside of the air bearing pads, or supplied air from the gas supply port 211 flows out to the outside of the air bearing pads without being completely taken in by the gas intake port 215, and the inflow/outflow amount changes depending on the support gap h. Thus, when the support gap h has changed, the wafer back surface pressure in the “intake groove” or the “outer peripheral land” portion fluctuates and tends to deviate from predetermined support characteristics. FIG. 8 also illustrates that variations in the pressure outside the air bearing pad 210 can affect the pressure in the intake groove. When the wafer chuck rotates at a high speed, a rotational centrifugal force acts on the gas flowing between the air bearing pads, and the pressure distribution on the back surface of the wafer changes. Thus, the pressure on the outer side of the air bearing pad fluctuates and deviates from a predetermined support characteristic, and the support gap or the wafer flatness may be easily affected by the rotation.

The upper part of FIG. 9 is a top view of the wafer chuck 202 in which a plurality of single air bearing pads 210 illustrated in FIG. 7 are disposed. The air bearing pads 210 are disposed at positions of 210P, 210Q, 210R, and 210S depending on the radial direction from the center toward the outer periphery. The lower part of FIG. 9 illustrates the pressure distribution on the back surface of the wafer and the support gap according to the position (distance from the chuck center) in the chuck radial direction of the wafer chuck 202 in the upper B-B′ part of FIG. 9. As illustrated in the lower part of FIG. 9, the wafer back surface pressure changes from the central portion of the wafer chuck toward the outside. That is, the wafer back surface pressure gradually decreases up to the air bearing pads 210P, 210Q, and 210R, greatly decreases at the outermost periphery 210S, and becomes the atmospheric pressure at the wafer chuck outer edge portion. The support gap has an outer height reflecting the wafer back surface pressure distribution. This is considered to be because the supply to the air bearing pad 210 and the intake are not balanced, and the gas flows out to the outside of the air bearing pad 210 or flows in from the outside to cause the pressure change in the outside portion of the air bearing pad, and the high-speed rotation of the wafer chuck affects the flow at the outside portion of the air bearing pad, which affects the support characteristics of the air bearing pad 210 and the pressure distribution on the back surface of the wafer from the central portion toward the outer peripheral portion of the wafer chuck.

As described above, in the wafer chuck in which the single air bearing pad illustrated in FIG. 9 is disposed without sharing the intake groove with adjacent pads, it is difficult to stably obtain predetermined support characteristics and support gaps because of the flow rate balance between supply and intake and the action of the centrifugal force of high-speed rotation. In comparison, in Example 1 illustrated in FIG. 2, the intake groove 116 is disposed so as to be shared between adjacent air bearing pads, and the flow rate balance between supply and intake is set for each air bearing pad. As a result, as illustrated in FIG. 6, even when the support gap h has changed, the predetermined support characteristic can be stably obtained even in high-speed rotation. It is understood that this effect is obtained by the configuration of the example illustrated in FIG. 2.

In addition, when the wafer chuck 102 according to the present example illustrated in FIGS. 2 and 4 is used, as described above in relation to the setting of the support characteristics in FIGS. 2 and 4, constant line velocity (CLV) inspection in which the rotation speed is changed during the inspection to have a constant linear speed can also be applied.

As described in FIG. 1, in the wafer inspection device 100 of the present invention, the entire surface of the wafer 101 is spirally inspected by the optical inspection unit 107 because of the rotational movement with the rotation mechanism unit 105 and the translational movement with the translation mechanism unit 106. The rotational movement with the rotation mechanism unit 105 is performed such that the rotation speed is constant when a wafer chuck of a back surface air floating type before an air bearing type is used. This corresponds to constant angular velocity (CAV). In the back surface air floating method, when the rotation speed has changed, the pressure distribution and the floating force of the back surface air of the wafer change because of the action of the centrifugal force, and the flatness Of the wafer changes. Thus, in the case of using a wafer chuck of the back surface air floating type, the rotation speed during inspection needs to be constant.

On the other hand, to improve the throughput of the wafer inspection, the CLV inspection in which the rotation speed during the inspection is variable under a constant linear speed is effective. In the case of the CAV inspection in which the rotation speed is constant, the movement speed of the wafer in the circumferential direction at the inspection point is slower in the inner peripheral portion and faster in the outer peripheral portion. In general, since the inspection sensitivity is limited by the moving speed of the inspection point, the inspection sensitivity has a tolerance on the inner circumference as compared with the outer circumference in the CAV inspection. Thus, when the CLV inspection is performed at a constant linear speed, the moving speed of the inspection point in the circumferential direction is increased by increasing the rotation speed during the inspection on the inner circumference, and thus, it is possible to improve both the sensitivity and the throughput of the wafer inspection.

Further, as an example of the optical inspection unit 107 in the example in FIG. 1, by using a short-wavelength deep ultraviolet laser as the irradiation optical system 107b, irradiating the inspection position 107a with a long elliptical beam with the deep ultraviolet laser to form an inspection region, and using an imaging optical system as the detection optical system 107c aligned with the inspection position 107a and a line sensor as the detection sensor 107e to form an image of the inspection region with the long elliptical beam on the imaging element on the line sensor, the sensitivity and the throughput of the optical inspection can be improved. With such a configuration of the optical inspection unit 107 and by further applying the above-described CLV inspection with a constant linear speed, further higher sensitivity and higher throughput of the optical inspection because of a synergistic effect of both can be realized. The line sensor scans an inspection point moving at a constant line rate, that is, at a constant speed, for one line at regular intervals. Thus, the line sensor is suitable in the CLV inspection in which the linear velocity is constant.

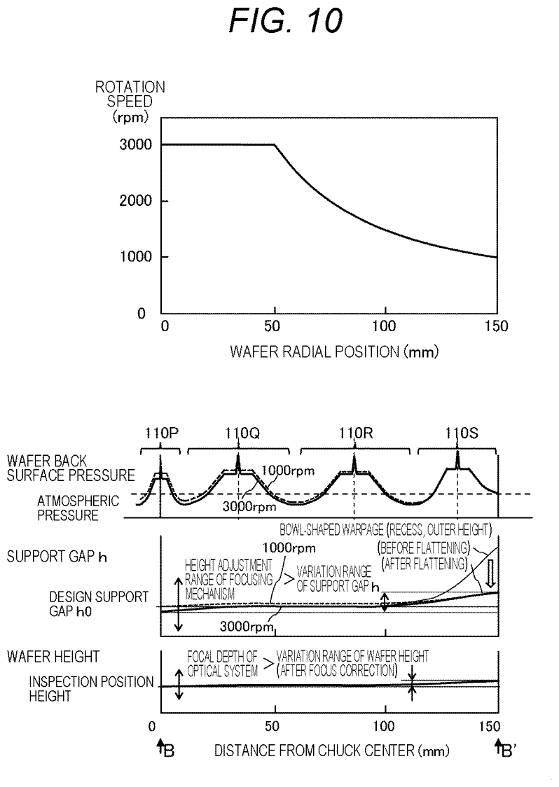

For example, in the rotation speed profile of the CLV inspection illustrated in the upper part of FIG. 10, the rotation speed in the inner peripheral portion is high, and the rotation speed during the inspection is 3000 rpm in the inner peripheral portion and 1000 rpm in the outer peripheral portion. In this case, the moving speed of the inspection point is the same as 15.7 m/s on both the outer periphery (position with a radius of 150 mm) and the inner periphery (position with a radius of 50 mm). The moving speed of the inspection point on the inner periphery (position with a radius of 50 mm) can be increased by three times as much as 5.2 m/s when the rotation speed is constant at 1000 rpm.

Here, in the wafer inspection device using the wafer chuck of the air bearing type according to the present example, the centrifugal force due to the rotation acts on both “wafer back surface air” present in the support gap h between the back surface of the wafer 101 and the wafer chuck 102 and “air in pipe” present in the gas supply pipe 121 and the gas intake pipe 122 in the lower part of FIG. 2. In the CLV inspection, it is necessary to pay attention to the influence of a change in the rotation speed, that is, a change in the action of the centrifugal force on them.

Among them, regarding the “wafer back surface air”, as described in the example of FIG. 2, by setting the design support gap to 0.1 mm or less, the flow between the wafer 101 and the wafer chuck 102 becomes a viscous flow and becomes less susceptible to the rotational centrifugal force. Thus, the influence of the variation of the support gap due to the rotation speed can be reduced.

The “air in pipe” acts so that the pressure loss due to the supply orifice 113 and the intake orifice 117 is hardly affected by the rotational centrifugal force. In the lower part of FIG. 2, the supply air is supplied from the gas supply pipe 121 to the back surface of the wafer through the supply orifice 113, and the intake gas is taken in from the gas intake pipe 122 from the back surface of the wafer through the intake orifice 117. Here, by applying a pressure loss corresponding to the supply pressure Ps at the supply orifice 113 to the gas supply and a pressure loss corresponding to the intake pressure Pv at the intake orifice 117 to the gas intake, the influence on the back surface pressure of the wafer can be reduced even when a centrifugal force acts on the “air in pipe” of the gas supply pipe 121 and the gas intake pipe 122 change the pressure distribution.

As described above, in a general static pressure bearing such as an air spindle, a pressure loss is given to air supply at the supply orifice, a high pressure is supplied to the support gap, and characteristics as a static pressure bearing are obtained. Thus, an intake structure is not required or provided. Even though an intake structure is provided depending on the application use, providing an intake orifice to give a pressure loss is not required in the intake path to obtain the support characteristics of the static pressure bearing, but rather, from the design theory of the static pressure bearing, it is regarded as interrupting intake characteristics and intake efficiency. Even in the prior art documents, neither PTL 1 nor PTL 2 describes a configuration requirement that gives a pressure loss to an intake path.

The inventors of the present invention have conceived that the configuration requirements of the present invention, in particular, the intake orifice is provided in the intake path in order to cope with the problem of the wafer chuck corresponding to the high-speed rotation of the wafer chuck or the CLV inspection in which the rotation speed is variable.

Actually, according to the study of the inventors of the present invention, when a predetermined supply pressure and intake pressure are applied at a rotation speed of 3000 rpm, and the supply orifice 113 exceeds 1 mm in diameter or the intake orifice 117 exceeds 2 mm in diameter, the pressure distribution of “air in pipe” affects the distribution on the wafer back surface pressure, resulting in deviation from the predetermined support gap. When the numerical values are set to appropriate values in the range of the diameter of the supply orifice 113 of 0.3 to 1 mm and the diameter of the intake orifice 117 of 0.3 to 2 mm as described in the example illustrated in FIG. 2, the influence on the pressure distribution on the wafer back surface pressure, the support gap, and the wafer height variation can be sufficiently reduced by the effect of the pressure loss of the supply orifice and the intake orifice even when the centrifugal force due to the high-speed rotation of the wafer chuck acts on the “air in pipe” to generate the pressure distribution in the gas in the gas supply pipe 121 and the gas intake pipe 122.

The lower part of FIG. 10 illustrates the influence of the rotation speed of the wafer chuck on the pressure distribution on the back surface of the wafer, the support gap, and the wafer height variation. The characteristic at the rotation speed of 1000 rpm is added with a broken line to the characteristic at the rotation speed of 3000 rpm (indicated by a solid line) in the middle part of FIG. 6. These rotation speeds correspond to the rotation speeds of the inner peripheral portion 3000 rpm and the outer peripheral portion 1000 rpm in the CLV speed profile in the upper part of FIG. 10. As described in FIG. 6, the wafer back surface pressure is, from the central portion to the outer peripheral portion, slightly small at the pad 110P, and becomes the same value at 110Q and 110R, and the wafer back surface pressure becomes the atmospheric pressure at the outer portion at the outermost peripheral pad 110S. Accordingly, the support gap h is also slightly small at 110P of the innermost circumference, and is constant at 110Q and 110R. The action of the centrifugal force due to the rotation of the wafer chuck is larger at the rotation speed of 3000 rpm than at the rotation speed of 1000 rpm, and the back surface pressure of the wafer and the variation in the inner circumference and the outer circumference of the support gap are also large. However, when the support characteristics of the air bearing pad are set to correspond to the rotation speed of 3000 rpm, the variation range of the support gap becomes smaller than the height adjustment range of the focusing mechanism even at the rotation speed of 1000 rpm.

As illustrated in the upper part of FIG. 10, in the actual CLV inspection, the rotation speed changes so as to approach 3000 rpm on the inner circumference and 1000 rpm on the outer circumference. Accordingly, the wafer back surface pressure and the support gap illustrated in the lower part of FIG. 10 change along the solid line on the inner periphery and change to come close to the broken line on the outer periphery. Since the variation range of the support gap is kept smaller than the height adjustment range of the focusing mechanism, the variation of the wafer height is smaller than the focal depth of the optical system, and the wafer inspection can be performed.

From the above, in the wafer inspection device using the air bearing type wafer chuck according to the present example, the variation of the wafer height can be made smaller than the focal depth of the optical system, and the optical inspection in which only the edge of the wafer is held can be performed by correcting the variation of the support gap with the height adjustment function of the focusing mechanism even with respect to the CLV inspection in which the rotation speed is variable under a constant linear speed during the inspection. Alternatively, it is possible to provide a wafer inspection device of the “edge grip” type in which only an edge is held with the back surface of the wafer in a non-contact state that corresponds to CLV inspection in which the rotation speed is variable under a constant linear speed during inspection.

As described above, according to the present example, it is possible to provide a substrate-holding device capable of reducing a characteristic difference between pads and improving in-plane pressure uniformity, and an optical inspection device including the substrate-holding device.

Further, for the CLV inspection, the sensitivity and the throughput of the optical inspection can be further improved by using a short-wavelength deep ultraviolet laser as the irradiation optical system 107b in the optical inspection unit 107, irradiating the inspection position 107a with a long elliptical beam with the deep ultraviolet laser to form an inspection region, and using a line sensor as the detection sensor 107e to form an image of the inspection region with the long elliptical beam on the imaging element on the line sensor. As a result, an optical inspection in which only an edge of a wafer is held or a wafer inspection device of the “edge grip” type, which achieves both high sensitivity and high throughput, can be provided.

### Example 2

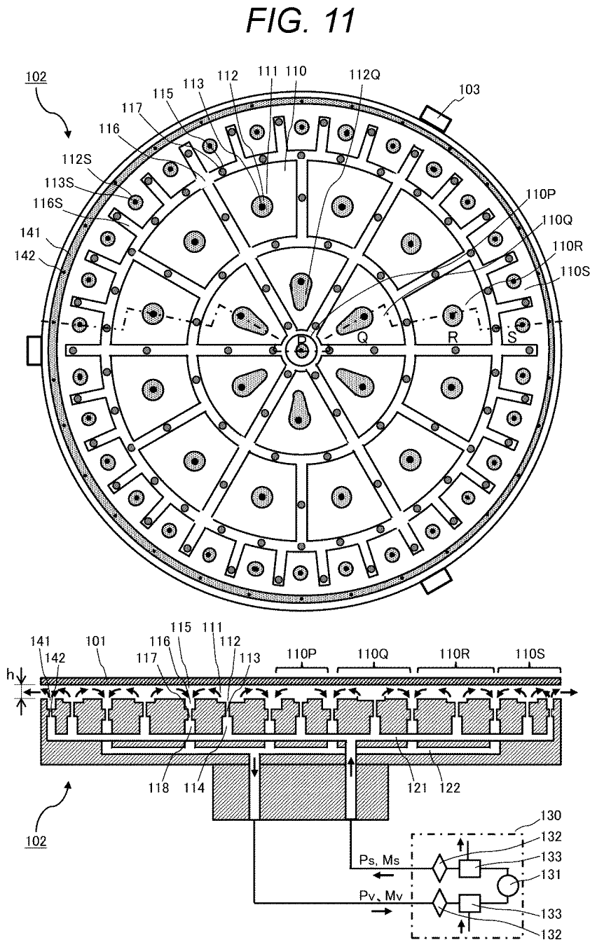

FIG. 11 includes a top view and a sectional view taken along the line A-A of a substrate-holding device (wafer chuck) according to Example 2 of the present invention. The present example is different from the above-described Example 1 in that, in the inner air bearing pad 110Q, the shape of the supply pocket 112Q is not a circle but an oval shape having a different radial length in the radial direction, and in the outermost peripheral air bearing pad 110S, a large number of air bearing pads 110S having a small area in which the lengths in the radial direction and the circumferential direction of the air bearing pad are reduced are disposed. The same components as those in Example 1 are denoted by the same reference numerals, and redundant description will be omitted below.

As illustrated in FIG. 11, each air bearing pad 110 includes the supply pocket 112, the supply orifice 113, and the static pressure bearing portion 114 as the gas supply port 111, and includes the intake groove 116 and the intake orifice 117 as the gas intake port 115, thereby constituting a static pressure air bearing (air bearing). The air bearing pads 110 are disposed adjacent to each other in the circumferential direction and the radial direction such that the intake groove 116 is shared with the adjacent air bearing pads.

In the inner air bearing pad 110Q, the shape of the supply pocket 112Q is not a circle but an oval shape having a radial length different in the radial direction. The inner air bearing pad 110Q has a substantially fan shape, and the interval between the intake grooves 116 disposed on both sides in the circumferential direction is narrowed on the side closer to the center. Thus, on the inner side close to the center, the intake locally exceeds the supply, and there is a possibility that the flow rates of gas supply and gas intake are not balanced. Thus, by making the supply pocket 112 oval, the supply amount from the gas supply port 111 is increased on the inner side close to the center, and the flow rates of gas supply and gas intake are also locally balanced.

In addition, in the outermost peripheral air bearing pad 110S, a large number of air bearing pads 110S having a small area in which the lengths in the radial direction and the circumferential direction of the air bearing pad are reduced are disposed. Although the supply pocket 112S is also small, the area ratio of the pocket portion to the air bearing pad is larger in the air bearing pad 110S than in the air bearing pads 110Q and 110R on the inner side. These are configured to obtain support characteristics with increased support rigidity corresponding to wafer warpage at the outermost periphery.

Further, an outer peripheral supply groove 141 is provided along the outermost periphery, and gas is supplied from an outer peripheral supply orifice 142 connected to the gas supply pipe 121 to the back surface of the wafer 101. Thus, the gas uniformly flows from the back surface of the wafer 101 toward the outer peripheral outside at the outermost periphery. This is to form a flow toward the outside at the outermost peripheral portion of the back surface of the wafer 101 so as to prevent foreign matters from adhering to the back surface of the end portion of the wafer 101 when a flow that may contain foreign matters is drawn from the outside of the wafer chuck 102. In FIG. 2, to realize the flow toward the outside at the outermost periphery of the back surface of the wafer 101, the intake groove 116 is not formed in the outer peripheral outer portion of the outermost peripheral air bearing pad 110S. On the other hand, as illustrated in FIG. 11, in the present example, the outer peripheral supply groove 141 continuously formed between the pads adjacent in the circumferential direction is provided on the outer peripheral side portion of the air bearing pad 110S, and when gas is supplied from the outer peripheral supply orifice 142, the flow of gas toward the outside at the outermost periphery of the back surface of the wafer 101 illustrated in the lower part of FIG. 11 becomes more uniform in the circumferential direction. Since the outer peripheral supply orifice 142 has a hole diameter different from that of the supply orifice 113, it is possible to supply gags at an optimum pressure and flow rate for air flow control in the outermost peripheral portion while being connected to the same supply pipe 121. With this configuration, the wafer can be held in a back surface non-contact manner without attaching foreign matters to the back surface of the end portion of the wafer 101.

As described above, according to the present example, in addition to the effect of the Example 1, the flow of gas toward the outside at the outermost periphery of the back surface of the wafer can be made more uniform in the circumferential direction.

In addition, the wafer can be held in a back surface non-contact manner without attaching foreign matters to the back surface of the end portion of the wafer.

### Example 3

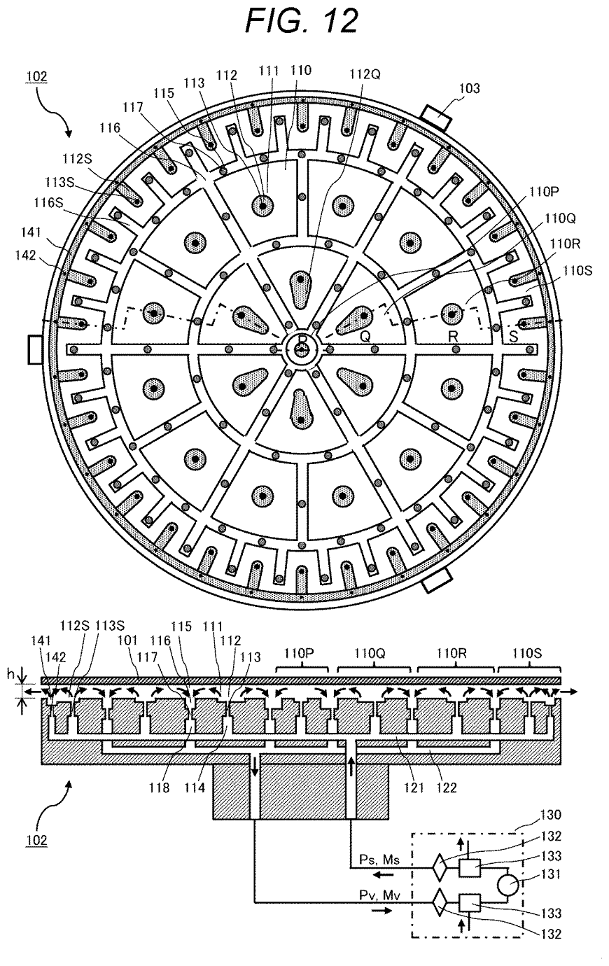

FIG. 12 includes a top view and a sectional view taken along the line A-A of a substrate-holding device (wafer chuck) according to Example 3 of the present invention. The present example is different from Example 1 in that the supply pocket 112S is connected to the outer peripheral supply groove 141 in the outermost peripheral air bearing pad 110S. The same components as those in Example 1 are denoted by the same reference numerals, and redundant description will be omitted below.

As illustrated in FIG. 12, the supply pocket 112S and the intake groove 116S are disposed in a comb shape so as to face each other, and since the intake groove 116S is disposed so as to surround the supply pocket 112S, the support characteristic of the outermost peripheral air bearing pad 110S as a static pressure bearing can be improved. Further, it is also possible to supply a part of the gas supplied from the supply pocket 112S to the outer peripheral supply groove 141 to supplement the gas supplied from the outer peripheral supply orifice 142. With an appropriate design, it is possible to configure such that the gas uniformly flows from the back surface of the wafer 101 toward the outer peripheral outside at the outermost periphery by supplying the gas supplied from the supply pocket 112S to both the supply pocket 112S and the outer peripheral supply groove 141 without providing the outer peripheral supply orifice 142.

According to the present example, in addition to the effect of Example 1, the support characteristics of the outermost peripheral air bearing pad as a static pressure bearing can be improved.

The present invention is not limited to the above-described examples but includes various modifications. For example, the above-described examples have been described in detail for easy understanding of the present invention, and the present invention is not necessarily limited to those having all the described configurations.

### Reference Signs List

100 wafer inspection device
101 wafer
102 wafer chuck
103 edge-holding mechanism
104 focusing mechanism unit
105 rotation mechanism unit
106 translation mechanism unit
107 optical inspection unit
107a inspection position
107b irradiation optical system
107c detection optical system
107d detection lens
107e detection sensor
107f wafer height measurement system
110 air bearing pad
111 gas supply port
112 supply pocket
113 supply orifice
114 static pressure bearing portion
115 gas intake port
116 intake groove
117 intake orifice
118 gas supply passage
119 intake passage
121 gas supply pipe
122 gas intake pipe
130 gas supply/intake system
131 pump
132 clean filter
133 pressure/flow rate control valve
141 outer peripheral supply groove
142 outer peripheral supply orifice
202 wafer chuck
210 air bearing pad (circular)
211 gas supply port
212 supply pocket
213 supply orifice
214 static pressure bearing portion
215 gas intake port
216 intake groove (annular)
217 intake orifice

1. A substrate-holding device comprising:
a rotary chuck; and
a clamp unit that supports an edge of a substrate to be rotated by the rotary chuck, in a radial direction and a circumferential direction of the substrate,
wherein the rotary chuck is provided with a plurality of static pressure bearing pads that hold the substrate in a back surface non-contact manner, the plurality of static pressure bearing pads including:
a plurality of gas supply ports that supplies gas to the substrate;
an intake groove disposed in the radial direction and the circumferential direction in a mutually connected manner;
one or a plurality of gas intake ports provided in the intake groove; and
a static pressure bearing portion provided between the gas supply ports and the intake groove, and
the intake groove and the one or plurality of gas intake ports are provided at positions shared with static pressure bearing pads adjacent to each other in the radial direction and the circumferential direction among the plurality of static pressure bearing pads.

2. The substrate-holding device according to claim 1, wherein each of the gas supply ports includes a supply orifice and a pocket portion and supplies gas to a back surface of the substrate.

3. The substrate-holding device according to claim 2, wherein the one or the plurality of gas intake ports provided in the intake groove includes an intake orifice and take in gas from the back surface of the substrate through the intake orifice.

4. The substrate-holding device according to claim 3, wherein the plurality of static pressure bearing pads provided on the rotary chuck has support characteristics based on positions in the radial direction of the rotary chuck, has substantially the same support characteristics in the circumferential direction at the respective positions in the radial direction, and is disposed in such a manner that the intake groove and the gas intake ports are shared with the static pressure bearing pads adjacent to each other in the circumferential direction and the radial direction.

5. The substrate-holding device according to claim 4, wherein the plurality of static pressure bearing pads provided on the rotary chuck are set such that a flow rate of gas supply from the gas supply ports and a flow rate of gas intake from the one or plurality of gas intake ports provided in the intake groove are equal for each of the static pressure bearing pads.

6. The substrate-holding device according to claim 3, wherein the gas supply ports include the pocket portion having a large flow path area and the supply orifice communicating with the pocket portion and formed below the pocket portion, the supply orifice having a flow path area smaller than that of the pocket portion.

7. The substrate-holding device according to claim 6, wherein the one or plurality of gas intake ports includes the intake orifice having a flow path area smaller than that of the intake groove.

8. The substrate-holding device according to claim 6, wherein the plurality of gas supply ports is connected to a gas supply flow path, and the plurality of gas intake ports are connected to a gas intake flow path.

9. The substrate-holding device according to claim 7, wherein the plurality of gas supply ports is connected to a gas supply flow path, and the plurality of gas intake ports are connected to a gas intake flow path.

10. An optical inspection device comprising a substrate-holding device that holds a substrate, a focusing mechanism unit on which the substrate-holding device is placed, a rotation mechanism unit that rotates the focusing mechanism unit, a translation mechanism unit that translates the rotation mechanism unit, and an optical inspection unit including an irradiation optical system and a detection optical system, wherein
the substrate-holding device includes:
a rotary chuck; and
a clamp unit that supports an edge of a substrate to be rotated by the rotary chuck, in a radial direction and a circumferential direction of the substrate,
the rotary chuck is provided with a plurality of static pressure bearing pads that hold the substrate in a back surface non-contact manner, the plurality of static pressure bearing pads including:
a plurality of gas supply ports that supplies gas to the substrate;
an intake groove disposed in the radial direction and the circumferential direction in a mutually connected manner;
one or a plurality of gas intake ports provided in the intake groove; and
a static pressure bearing portion provided between the gas supply ports and the intake groove, and
the intake groove and the one or plurality of gas intake ports are provided at positions shared with static pressure bearing pads adjacent to each other in the radial direction and the circumferential direction among the plurality of static pressure bearing pads.

11. The optical inspection device according to claim 10, wherein each of the gas supply ports includes a supply orifice and a pocket portion and supplies gas to a back surface of the substrate.

12. The optical inspection device according to claim 11, wherein the one or the plurality of gas intake ports provided in the intake groove includes an intake orifice and take in gas from the back surface of the substrate through the intake orifice.

13. The optical inspection device according to claim 12, wherein the plurality of static pressure bearing pads provided on the rotary chuck has support characteristics based on positions in the radial direction of the rotary chuck, has substantially the same support characteristics in the circumferential direction at the respective positions in the radial direction, and is disposed in such a manner that the intake groove and the gas intake ports are shared with the static pressure bearing pads adjacent to each other in the circumferential direction and the radial direction.

14. The optical inspection device according to claim 13, wherein the plurality of static pressure bearing pads provided on the rotary chuck are set such that a flow rate of gas supply from the gas supply ports and a flow rate of gas intake from the one or plurality of gas intake ports provided in the intake groove are equal for each of the static pressure bearing pads.

15. The optical inspection device according to claim 14, wherein
the substrate-holding device, the focusing mechanism unit, the rotation mechanism unit, and the optical inspection unit are configured such that
during inspection in optical inspection,
the rotation mechanism unit rotates the substrate-holding device at a constant linear speed, the static pressure bearing pads provided in the substrate-holding device flatten and hold a warpage of the substrate held by the substrate-holding device in a back surface non-contact manner within a range of height position correction performed by the focusing mechanism unit, and a height of the substrate is within a range of a focal depth of the optical inspection unit.

16. The optical inspection device according to claim 15, wherein the irradiation optical system forms an inspection region with an illumination optical system irradiating an inspection position with a long elliptical beam, and forms an image of the inspection region on a line sensor that is a detection sensor with an imaging optical system aligned with the inspection position.
